(19) United States
(12) Patent Application Publication
(10) Pub. No.: US 2019/0148367 A1
(43) Pub. Date: May 16, 2019

(54) 3D CIRCUIT WITH N AND P JUNCTIONLESS TRANSISTORS

(71) Applicant: COMMISSARIAT A L'ENERGIE ATOMIQUE ET AUX ENERGIES ALTERNATIVES, Paris (FR)

(72) Inventors: Jean-Pierre Colinge, Grenoble (FR); Sylvain Barraud, Le Grand Lemps (FR); Perrine Batude, Dijon (FR)

(73) Assignee: COMMISSARIAT A L'ENERGIE ATOMIQUE ET AUX ENERGIES ALTERNATIVES, Paris (FR)

(21) Appl. No.: 16/184,346

(22) Filed: Nov. 8, 2018

(30) Foreign Application Priority Data
Nov. 10, 2017 (FR) 17 60616

(51) Int. Cl. H01L 27/06; H01L 21/822; H01L 21/8234

(52) U.S. Cl. CPC H01L 27/0688; H01L 21/8221; H01L 21/823475; H01L 21/823418; H01L 21/823412

(57) ABSTRACT

Production of an integrated circuit provided with several superposed levels of transistors, comprising:
providing a structure provided with transistors of a lower level covered by an insulating layer itself covered by a stack with a first doped semi-conducting layer according to a doping of a first type, and a second doped semi-conducting layer according to a doping of opposite type, the first doped semi-conducting layer and the second doped semi-conducting layer being superposed and in contact with one another,
etching the stack so as to form, on the insulating layer, a first block and a second block, then,
removing in a given zone of the second block, the second given doped semi-conducting layer,
forming a first gate on the second doped semi-conducting layer of the first block and a second gate on the first doped semi-conducting layer of the second block.

### TECHNICAL FIELD AND PRIOR ART

The present application relates to the field of integrated circuits provided with components distributed over several levels. Such devices are generally qualified as three-dimensional or “3D” integrated circuits.

Generally, in the field of integrated circuits, the density of transistors is continuously sought to be increased.

For this, a solution consists of distributing the transistors over several levels of semi-conducting layers arranged on top of one another. Such circuits thus generally comprise at least two semi-conducting layers, superposed and separated from one another by an insulating layer.

Producing N type and P type transistors on the upper level may involve the implementation of one or more heat processing steps, in particular when the dopants are activated.

However, a high-temperature heat treatment can cause a degradation of the lower level(s), and in particular, a deterioration of the contact material in the lower level or of inter-level connection elements, even an unintentional diffusion of dopants within the lower level.

Once the first level of transistors is achieved, it is generally therefore sought to limit the thermal budget for producing the upper level(s) and to avoid in particular, implementing heat treatments greater than 550° C.

Therefore, the problem is posed of producing a 3D integrated circuit while using a reduced thermal budget.

Document WO 2014/162018 A1 proposes to implement a 3D circuit with junctionless transistors. Such a type of transistor has been presented, in particular in the document by Colinge et al., “Nanowire transistors without junctions” Nature Nanotechnology 5, 225-229 (2010).

Such transistors are generally formed in a doped layer having a single type of N or P conductivity, such that a current circulating between the source and the drain does not pass through a PN or NP junction.

In document WO 2014/162018 A1, N and P type junctionless transistors are arranged so as to produce an inverter and arranged on top of one another with an insulating layer interleaved between two semi-conducting layers respectively N doped and P doped.

Such an arrangement poses difficulties, in particular in terms of producing the stack of doped layers and contacts. Moreover, the arrangement proposed requires a common gate between the two transistors.

The problem of producing an N type and P type junctionless transistor device on one same support is posed, and which is improved regarding the disadvantage(s) mentioned above.

### DESCRIPTION OF THE INVENTION

An embodiment of the present invention provides a method for producing an integrated circuit provided with several superposed levels of transistors, the method comprising steps consisting of:
providing a structure provided with one or more transistors of a lower level covered by an insulating layer, itself covered by a stack comprising at least a first semi-conducting layer, doped according to a doping of a first type, N or P and at least a second semi-conducting layer, doped according to a doping of a second type, P or N, opposite said first type, the first doped semi-conducting layer and the second doped semi-conducting layer being superposed and in contact with one another,
etching the stack so as to form on the insulating layer, at least a first block and at least a second block, separate from the first block, then,
removing in at least a given zone of the second given doped semi-conducting layer, while preserving in this given zone, the first doped semi-conducting layer,
forming a first gate of a first transistor arranged on the second doped semi-conducting layer of the first block and a second gate of a second transistor arranged on the first doped semi-conducting layer of the second block.

The method may further comprise the formation of source and drain contacts of the first transistor on the second doped semi-conducting layer on either side of the first gate and other source and drain contacts of the second transistor on the first doped semi-conducting layer on either side of the second gate.

According to a possibility of implementing the method, the second doped semi-conducting layer is fully removed in said second block.

According to an advantageous embodiment, prior to the formation of the first gate, insulating plugs are formed on either side of the first doped semi-conducting layer, the insulating plugs being configured so as to electrically insulate the first gate of the first doped layer.

According to a specific embodiment wherein after formation of the first block and of the second block, on the second block, a sacrificial gate is made, and insulating spacers are made on either side of the sacrificial gate, the method may further comprise steps of:
removing the sacrificial gate so as to uncover the second doped semi-conducting layer in the second block, the removal of the second doped semi-conducting layer in the second block then being done by etching between the insulating spacers, then after this removal,
Forming a replacement gate on the second block.

According to a specific embodiment wherein after formation of the first block and of the second block, on the first block, a sacrificial gate is formed, and insulating spacers are formed on either side of the sacrificial gate, the method can further comprise steps of:
removing the sacrificial gate so as to disclose the first block,
removing the first doped semi-conducting layer in the first block by etching between the insulating spacers,
forming a replacement gate on the first block.

Advantageously, the method may further comprise, the formation of source and drain contacts, embedding on the first block and/or on the second block, the embedding contacts each being arranged in contact with the first doped semi-conducting layer and with the second doped semi-conducting layer.

Advantageously, the stack of doped layers is formed by extending over the insulating layer. Steps of increasing the doped semi-conducting layers and possible thermal anneal(s) can thus be carried out without altering the first level of transistors.

Typically, the stack is formed of one or more doped semi-conducting layers made of a first semi-conducting material and one or more doped semi-conducting layers made of a semi-conducting material, the removal in the given zone of the second block being done by selective etching of the first semi-conducting material opposite the second semi-conducting material.

The method may further comprise a removal in a region of the first block of doped semi-conducting layers based on the second semi-conducting material by selective etching opposite the first semi-conducting material.

Advantageously, the first doped semi-conducting layer is made of N doped silicon and the second doped semi-conducting layer is made of P doped silicon germanium.

In a variant, a reverse order of doped layer may be provided, the first doped semi-conducting layer being made of P doped silicon germanium and the second doped semi-conducting layer made of N doped silicon.

According to another aspect, the present application provides a microelectronic device with transistors distributed over several superposed levels comprising:
a structure provided with one or more transistors of a lower level covered by an insulating layer,
a second level of P and N type junctionless transistors arranged on the insulating layer, the second level of transistors comprising:
a first junctionless transistor formed in a first semi-conducting block comprising a stack of at least one first doped semi-conducting layer according to a doping of a first type, N or P and at least one second doped semi-conducting layer according to a doping of a second type, P or N, opposite said first type, the first transistor having a control gate electrode of a channel region which extends into the second doped semi-conducting layer,
a second junctionless transistor formed in a second semi-conducting block separate from the first block, and comprising said first doped semi-conducting layer, the second transistor having a gate for controlling a channel region which extends into said first doped semi-conducting layer.

The first transistor can further comprise source and drain contacts on the second doped semi-conducting layer, the second transistor comprising source and drain contacts on the first doped semi-conducting layer.

The first transistor can be advantageously provided with a channel region, in the form of a mesa or in the form of at least one fin, constituted of said second doped semi-conducting layer.

The second transistor may advantageously be a channel region, in the form of a mesa or in the form of at least one fin, constituted of said first doped semi-conducting layer.

The first transistor and/or the second transistor can be advantageously provided with embedding source and drain contacts, and each arranged in contact with the first doped semi-conducting layer and with the second doped semi-conducting layer.

### BRIEF DESCRIPTION OF THE DRAWINGS

The present invention will be better understood upon reading the description of given examples of embodiments, purely for information purposes and not at all limiting, by making reference to the appended drawings on which:

FIGS. 1A-1F are used to illustrate an example of an embodiment of P and N type junctionless transistors on a same support;

FIGS. 2A-2B are used to illustrate a variant of an embodiment wherein the channel regions of the transistors are in the form of mesas;

FIGS. 3A-3F are used to illustrate an embodiment wherein a junctionless transistor is formed from a stack of doping semi-conducting layers of opposite types, one of these layers being insulated by the gate by means of insulating plugs;

FIGS. 4A-4N are used to illustrate an embodiment wherein the junctionless transistors are formed from a stack comprising two doped semi-conducting layers according to dopings of opposite types, one of these layers being removed in order to form a channel structure comprising a doped layer according to a single type of N or P doping;

FIGS. 5A-5C are used to illustrate a variant of the method in FIGS. 4A-4J wherein the stack comprises more than two doped semi-conducting layers;

FIGS. 6A-6D are used to illustrate an example of a method for producing P and N type junctionless transistors on a support already comprising at least a transistor stage;

FIGS. 7A-7E are used to illustrate another example of a method for producing P and N type junctionless transistors on a support already comprising at least one transistor stage;

FIG. 8 is a flowchart giving an example of a sequence of steps likely to be implemented during a method according to an embodiment of the present invention;

FIG. 9 is a flowchart giving an example of a sequence of steps likely to be implemented during a method according to another embodiment of the present invention;

Identical, similar or equivalent parts of different figures have the same numerical references, so as to facilitate the passage from one figure to the other.

The different parts represented in the figures are not necessarily in accordance with a consistent scale to make the figures more legible.

Furthermore, in the description below, the terms which depend on the orientation, such as “on”, “above”, “upper”, “lower”, “lateral”, etc. of a structure are applied by considering that the structure is oriented in the manner illustrated in the figures.

### DETAILED DESCRIPTION OF SPECIFIC EMBODIMENTS

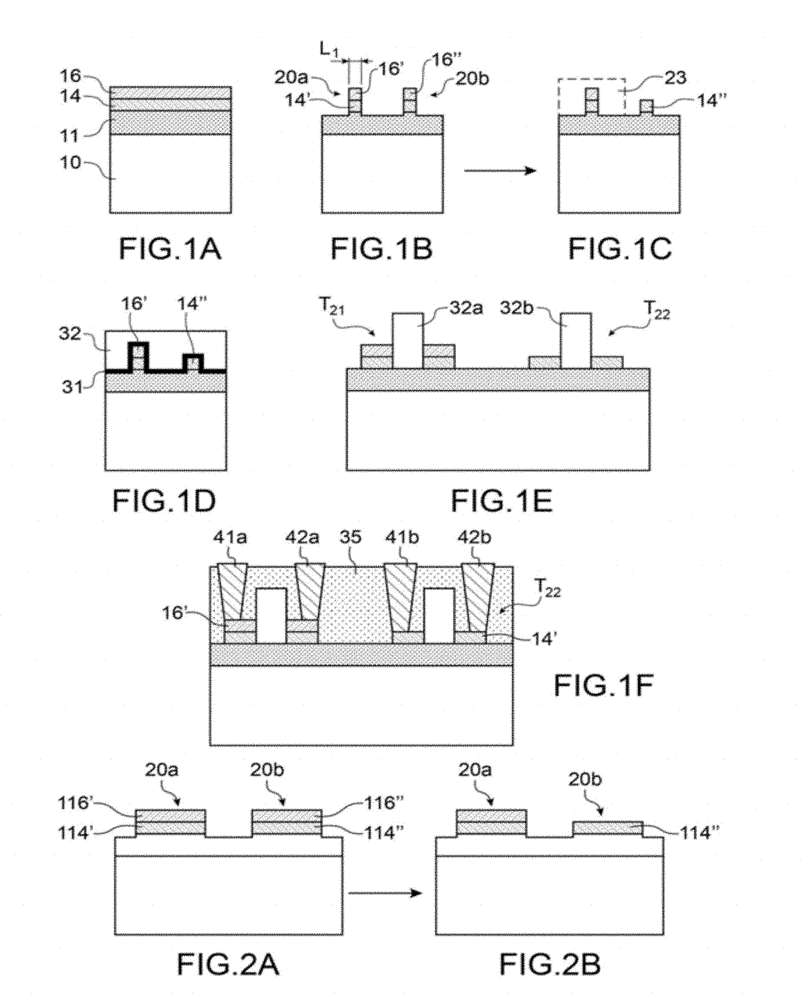

An example of a method for producing a junctionless transistor device among which at least one N type transistor and at least one P transistor arranged on one same support will now be given, in connection with FIGS. 1A-1F.

Firstly, FIG. 1A is referred to, which presents a support 10 covered by an insulating layer 11 on which a stack of doped semi-conducting layers 14, 16 is provided. In the illustrated example of a specific embodiment, the support is a semi-conducting layer, for example, of a substrate of semi-conductor on insulator type, the insulating layer 11 could, for example, be a silicon oxide layer.

The stack comprises a doped semi-conducting layer 14 according to a doping of a given type, in this example of N type, arranged on and in contact with the insulating layer 11. The first semi-conducting layer 14 is coated with a second doped semi-conducting layer 16 according to a doping of type opposite to the given type, consequently of P type in this example. In other words, the second semi-conducting layer 16 has a conductivity type opposite to that of the first semi-conducting layer 14.

The first semi-conducting layer 14 and the second semi-conducting layer 16 are preferably respectively with a base of a first semi-conducting material and of a second semi-conducting material, different from the second semi-conducting material, capable of being etched selectively opposite the first semi-conducting material. For example, the first semi-conducting layer 14 made of N doped silicon and the second semi-conducting layer 16 made of P doped silicon germanium are provided.

The semi-conducting layers 14, 16 are typically formed by epitaxy. The doping of these semi-conducting layers 14, 16 can be an in situ doping, in other words, done during epitaxial growth. The doping can also be done by other techniques, such as ion implantation followed by an activation annealing.

A later step of etching, preferably anisotropic, of the stack, enables to form on the insulating layer 11 at least a first block 20a and at least a second block 20b separate from the first block 20a.

In the example of a specific embodiment illustrated in FIG. 1B of the blocks 20a, 20b are each formed of a stack of bars 14′, 16′ for the first block 20a (respectively 14″, 16″ for the second block 20b) again called “fins”, superposed and respectively coming from the first N doped semi-conducting layer 14 and the second P doped semi-conducting layer 16. The fins 14′, 16′, 14″, 16″ have a width L₁ or critical dimension L₁ (in other words, the smallest dimension thereof apart from the thickness thereof) which can be, for example, between 4 and 20 nm.

FIG. 1C illustrates a later step of removal in the second block 20b of the fin 16″ coming from the second doped semi-conducting layer 16, whereas the fin 14″ coming from the first doped semi-conducting layer 14 is preserved. For example, to carry out a selective removal of silicon germanium opposite the silicon, a CF₄ or HCl-based etching is used. The first block 20a is itself preserved intact, for example, by using a protective mask 23 against the etching formed on this block 20a. A protective mask 23 made of a photosensitive resin or in the form of a hard mask can be used, for example.

The protective mask 23 is then removed.

Thus, a dielectric layer 31 and a layer of gate material 32 are formed (FIGS. 1D et 1E) on a portion of the first block 20a and of the second block 20b, in order to produce a first gate electrode 32a and a second gate electrode 32b respectively for a first transistor T₂₁ and for a second transistor T₂₂. The first gate 32a, extends over a region of the fin 16′ coming from the second semi-conducting layer 16 capable of forming a P doped channel of the first transistor T₂₁. The second gate 32b, itself extends over a region of the fin 14″ coming from the second semi-conducting layer 16 capable of forming a P doped channel of the first transistor T₂₁.

In the example illustrated, the gates 32a, 32b are called “embedding”, in other words, distributed over the top, as well as over the lateral faces of the channel regions.

In FIG. 1F, a subsequent step of forming conducting blocks 41a, 42a, 41b, 42b through an insulating layer 35 covering the transistors is illustrated. The first conducting blocks 41a, 42a are formed on either side of the first gate 32a respectively over the regions of the second P doped bar 16′ of the first block 20a. The second conducting blocks 42a, 42b to establish a contact over the regions of the N doped fin 14′ of the second block 20b are also formed. The source and drain contacts are thus implemented for the first transistor T₂₁ with a P doped channel and the second transistor T₂₂ with an N doped channel.

A silicide may also be placed or formed by chemical reaction on the source and drain regions before forming the conducting blocks 41a,b and 42a,b.

The transistors T₂₁, T₂₂ produced are “junctionless” type transistors, in other words, with doped source, drained and channel regions according to a same doping type, such that a current circulating between the source and the drain, and passing through the channel, is likely to not pass through the PN or NP junction, but a mainly N doped semi-conducting layer (layer 16′ for the transistor T₂₁) or mainly P doped (layer 14′ for the transistor T₂₂). By “mainly N doped”, this means that in the whole semi-conducting layer in question, exclusively a doping of a given type is provided, and which consists of producing excess electrons. By “mainly P doped”, this means that the whole semi-conducting layer in question, exclusively a doping of a type opposite to the given type is provided, which consists of producing excess holes.

In a variant of the example which has just been defined, the junctionless transistors may be produced in semi-conducting blocks of forms different from that, than in stacked fins or stacked bars, outlined above.

Thus, according to another example of an embodiment illustrated in FIG. 2A, this time, the semi-conducting blocks 20a, 20b are produced, each in the form of mesas 114′, 116′ (respectively 114″, 116″) of respective N and P stacked doping. The width of critical dimension of a mesa can be, for example, between 20 and 500 nm.

Then, a doped layer in a block 20b is removed, while protecting at least another block 20a of this etching. In the example illustrated in FIG. 2B, a P doped mesa in the second block 20b is removed by selective etching opposite the material of the N doped mesa 114″. The first block 20a is itself preserved. Thus, a transistor having a channel region extending into the P doped mesa 116″ of the first semi-conducting block 20a is then formed, whereas another transistor is provided with a channel region extending into the remaining and N doped mesa 114″ of the second semi-conducting block 20b.

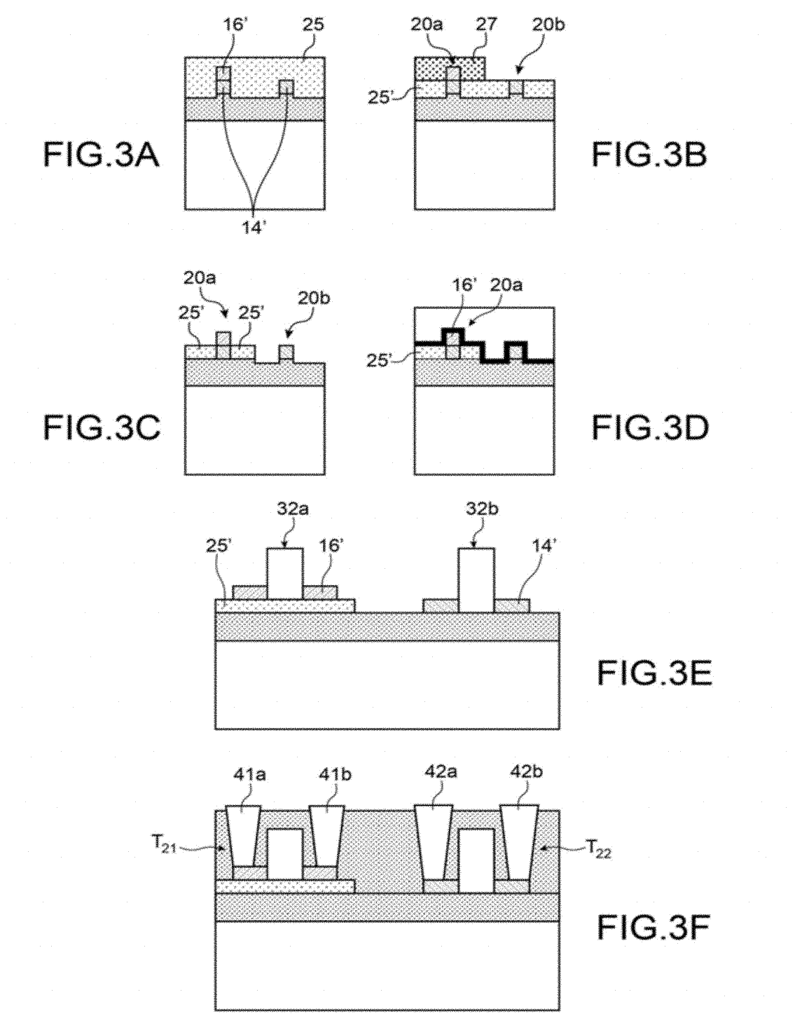

FIGS. 3A-3F illustrate a variant of an embodiment of either of the examples of embodiments defined above.

For this variant, after the step defined in line with FIG. 1C (or 2B), in other words, of selective removal of at least one doped zone of the second block 20b, lateral insulation zones are formed, again called “insulating plugs” on either side of the first semi-conducting layer 14 of the first block 20a. The insulating plugs 25′ are thus produced around the block 20a for which the stack of N and P doped semi-conducting layers 14, 16 have been preserved, without etching or removing the upper doped semi-conducting layer 16. Producing the insulating plugs 25′ is advantageously done after removing the second semi-conducting layer 16 (upper bar 16″ or upper mesa 116″) in the second block 20b, the first block 20a and the second block 20b thus having different respective heights.

To form these insulating plugs, firstly a deposit of insulating material 25 can be made, for example, silicon oxide so as to cover the first block 20a and the second block 20b (FIG. 3A).

Then, a thickness of this insulating material 25 is removed, for example by CMP (Chemical Mechanical Planarisation), preferably until reaching the upper face of the blocks 20a, 20b.

Then, a removal of a thickness of insulating material 25 is carried out, for example by etching, so as to remove a thickness of insulating material 25 corresponding to the height or substantially to the height of the second semi-conducting layer 16.

Then, the insulating material 25 on and around the second block 20b can be removed. To do this, typically a photolithography method is used, in order to form a mask 27 protecting the first block 20a, whereas the second block 20b is not covered by this mask. Then, the non-masked portion of the layer of insulating material 25 is etched. A photosensitive mask 27 or mask of hard type can be used. This mask 27 is then removed.

Zones called plugs 25′ of insulating material 25 are thus preserved on the lateral faces of the first doped layer 14 of the first block 20a, whereas the lateral and upper faces of the second block 20b are themselves disclosed (FIG. 3C).

Then (FIGS. 3D-3E), gate electrodes 32a, 32b are formed, respectively on the first block 20a and on the second block 20b. On the first block 20a, a surrounding gate is thus produced around the lateral and upper faces of the second doped semi-conducting layer 16. The insulating plugs 25′ enable to produce an electrical insulation between the first doped layer 14 of the first block 20a and the first gate electrode 32a.

Then, the source 41a, 42a and drain 41b, 42b contacts are produced, respectively for the first transistor T₂₁, and for the second junctionless transistor T₂₂ (FIG. 3F).

A junctionless transistor device such as implemented according to the invention can be in a variant, provided with transistors having a channel structure formed from the stack of doped layers 14, 16 such as defined above, but wherein a portion of N or P doped layers are removed.

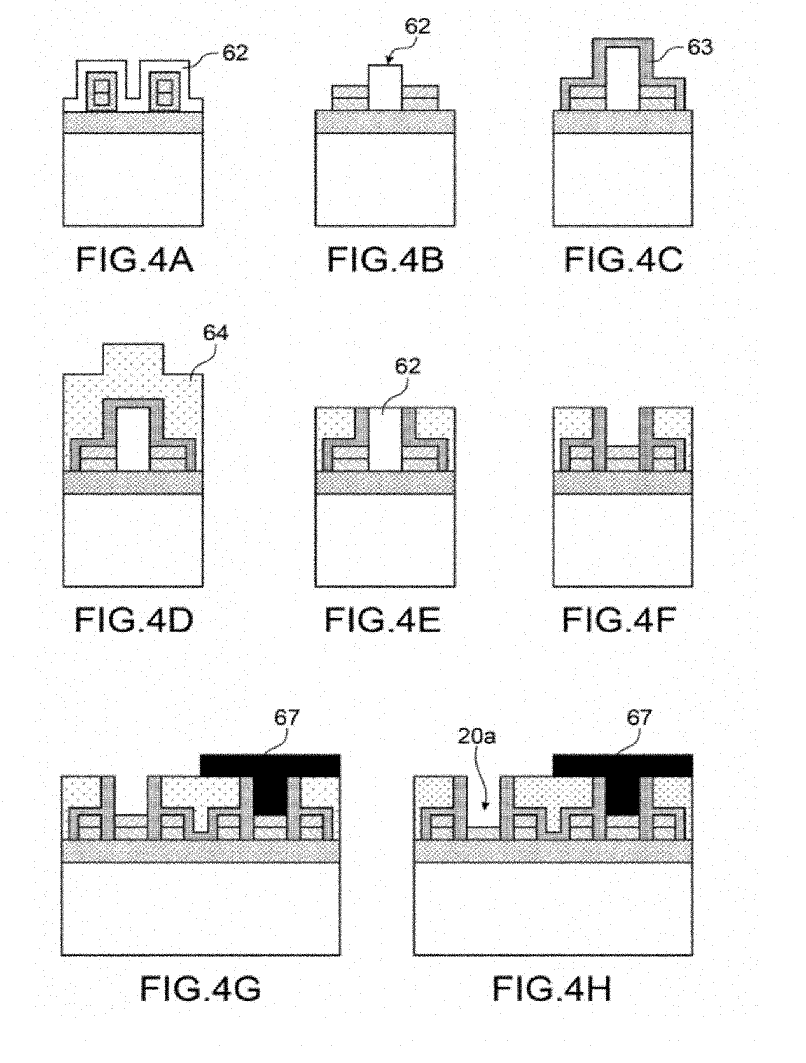

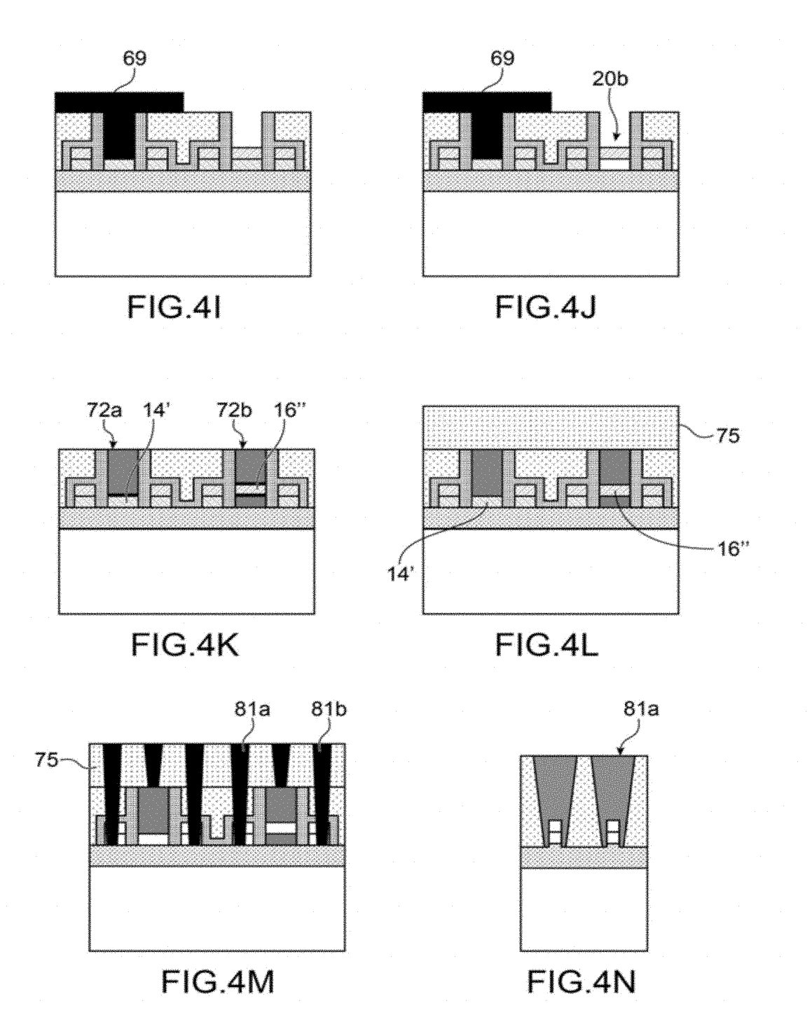

An example of an embodiment of such a device is given in FIGS. 4A-4N.

After forming the separate semi-conducting blocks 20a, 20b, a step of producing sacrificial gates such as illustrated in FIGS. 4A-4B is implemented. Producing the sacrificial gates typically comprises the deposit of a sacrificial gate material 62, for example, polysilicon, and forming patterns in this material, typically by photolithography.

Then, the insulating spacers 65 are formed. This can be achieved by depositing dielectric material 63, such as for example silicon nitride on the separate blocks 20a, 20b and on the sacrificial gates 62 (FIG. 4C). Then, a protective layer 64 is deposited, which can be insulating and for example, made of silicon oxide (FIG. 4D). Then, a planarisation of the protective layer 64 is carried out, typically by CMP polishing, so as to disclose the upper face (in other words, the top) of the sacrificial gate patterns (FIG. 4E).

Then, the sacrificial gates are removed (FIG. 4F), whereas the spacers 65 and the protective layer 64 are themselves preserved. When the gate material 62 is polysilicon, this removal can be achieved, for example, using a selective plasma etching using gases such as SF₆, Cl₂ or HBr.

Then, in the specific example of method illustrated, a removal is made in the first block 20a of a given zone of the second P doped semi-conducting layer 16, which is situated between the spacers 65. This removal is typically achieved by etching the material of the second selective doped semi-conducting layer 16 opposite that of the first doped semi-conducting layer 14. For example, when the second doped semi-conducting layer 16 is made of SiGe and the first doped semi-conducting layer 14 made of Si, a removal of the SiGe is made using HF steam or HCl.

Thus, a zone for stacking the layers 14, 16 situated between the spaces 65 is etched, while reserving the stack zones situated around or on either side of the spacers 65. The second block 20b can be preserved from this etching by using a masking 67, for example formed by photolithography, filling the placement left by the removal of the sacrificial gate (FIG. 4G).

FIG. 4H illustrates a cross-sectional view of the first block 20a from this etching. Thus, a transistor channel region is obtained, only constituted of N doped material.

Then, in the second block 20b, the removal of a given zone of the first doped semi-conducting layer 14 is carried out, in this N doped example, which is situated between the spacers 65. Thus, a zone for stacking the layers 14, 16 situated between the spacers 65 is etched, while preserving the stack zones situated around or on either side of spacers 65. The first block 20a can be preserved from this etching by using a masking 69, for example formed by photolithography, filling the placement left by the removal of the sacrificial gate (FIG. 4I).

The removal is thus typically done by selective etching of the material of the first doped semi-conducting layer 14 opposite that of the second doped semi-conducting layer 16. For example, when the second doped semi-conducting layer 16 is made of SiGe, and the first doped semi-conducting layer 14 made of Si, a removal of the Si using, for example, TMAH (Tetramethylammonium hydroxide) or a CF₄:H₂ plasma is done.

FIG. 4J illustrates a cross-sectional view of the second block 20b coming from this etching. Then, the masking 69 is removed.

FIG. 4K illustrates a later step of forming a replacement gate 72 on a portion of the blocks 20a, 20b situated between the spacers 65. To do this, a gate dielectric is typically deposited, such as for example, HfO₂ and a gate material, such as for example W.

Thus, a gate 72a partially embedding around lateral faces and an upper face of an N doped fin 14′ and a gate 72b totally embedding around an upper face, a lower face, and lateral faces of a P doped fin 16″ are obtained.

Once the gates 72a, 72b are obtained, the transistors may be covered by an insulating layer 75, for example, made of silicon oxide (FIG. 4L).

Then, source and drain contacts 81a, 81b may be formed, on either side of the gate (FIG. 4M) and passing through the insulating layer 75. The contacts 81a, 81b can advantageously have an embedding structure and extend over an upper face, as well as the lateral faces of the stack of semi-conducting layers 14, 16. As can be seen in FIG. 4N, a contact 81a can thus be arranged in contact, both with the first doped semi-conducting layer 14 and with the second doped semi-conducting layer 16. Such an arrangement is permitted, in particular because the channel structure, here is formed from a fin, of P or N type doping, which is not in contact with an opposing conductivity layer.

The order of the N and P doped layers of the stack could be reversed, in a variant, a device with a transistor having a partially embedding gate around a P doped fin and a totally surrounding gate around an N doped fin can be implemented.

According to another variant of the example of the method which has just been defined, it can be provided to carry out the steps defined in line with FIGS. 4G, 4J in a different order, in other words, by firstly removing the first doped layer 14 in a zone of the second block 20b, then by removing the second doped layer 16 in a zone of the first block 20a.

Another variant of the example of the method which has just been defined, provides to not selectively remove the doped layer on one of the blocks 20a or 20b, in other words, to only carry out the steps defined in line with FIG. 4G-4H without carrying out the steps in FIGS. 4I-4J, or only carrying out the steps defined in line with FIG. 4I-4J without carrying out the steps in FIGS. 4G-4H.

Either of the examples of the methods which have just been defined, can be applied to the implementation of junctionless transistors from a stack having more than two doped semi-conducting layers, and in particular comprising an alternation of several N doped semi-conducting layers and of several P doped semi-conducting layers.

Thus, a junctionless transistor device can be produced, provided with a channel structure comprising several doped fins arranged on top of one another.

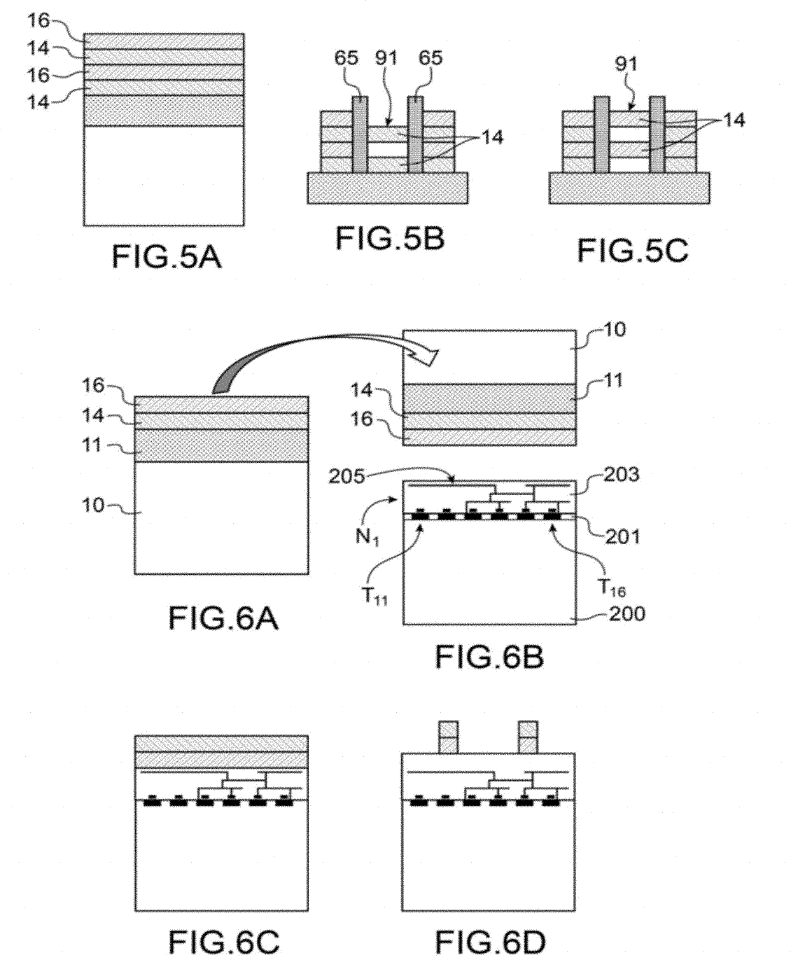

For example, a stack such as in FIG. 5A can be provided, with a first superposition of respectively N and P doped layers 14, 16, on which a second superposition of respectively N and P doped layers 14, 16 are formed.

As indicated above, the order of the N and P layers in the alternation of layers can be reversed. In the example illustrated, the stack comprises k=4 doped layers. The number k of doped layers of the stack can however be greater, for example, 6 or 8 doped layers.

Then, the blocks 20a, 20b are defined in this stack. Then, a method such as defined above in line with FIGS. 4A-4H can be implemented.

In particular, a sacrificial gate can be formed on at least one block defined in the stack and from the insulating spacers 65 against this sacrificial gate.

Then, a removal of the sacrificial gate is done, so as to disclose a zone called “central” of this block. Then, a selective etching of the material of the layers having a given N or P doping type is done, opposite that of the layers having a P or N opposite type doping.

In the example of an embodiment illustrated in FIG. 5B, these are P doped semi-conducting layers 16, for example made of SiGe, which are selectively etched opposite the N doped semi-conducting layers 14, for example made of Si. Thus, a channel structure 91 can be obtained with semi-conducting fins arranged on top of one another and N doped.

In the example of an embodiment illustrated in FIG. 5C, these are the P doped semi-conducting layers 16, for example made of SiGe, which are selectively etched opposite the N doped semi-conducting layers 14 and typically made of a different semi-conducting material, such as for example, Si. A channel structure 92 can also be obtained, with semi-conducting fins arranged on top of one another and P doped.

A method such as defined above, can be implemented from a type of support, different from that which has just been defined.

According to a particularly advantageous embodiment, instead of a semi-conductor substrate on insulator type support, the method defined above can be applied to a structure already comprising at least one level of transistors.

In this case, the stack of doped semi-conducting layers 14, 16 is formed or returned over a structure already comprising at least one semi-conducting layer wherein the channel regions of transistors extend.

Thus, the junctionless transistors T₂₁, T₂₂ are produced in an upper stage of a device comprising several levels of transistors.

An N and P type junctionless transistor device such as defined above is adapted therefore, most specifically to an integration in an integrated three-dimensional or “3D” circuit. In such circuits, transistors are distributed over several levels of semi-conducting layers or semi-conducting stacks.

A difficulty in surmounting to achieve such a circuit, comes temperature limits to which an upper level of components can be subject to, without degrading the lower level(s).

The integration of a junctionless transistor device superposed in the upper semi-conducting level of an integrated circuit enables to avoid steps of annealing or treatment are a high temperature, generally carried out to activate the dopants and to define the junctions of the transistors. Thus, a degradation of the conducting material is avoided, on the base of which the inter-level connection elements are formed. Thus, a non-sought diffusion of dopants within the lower level(s) is also avoided.

To implement such a 3D circuit, it can be provided to produce the stack of doped semi-conducting layers 14, 16 on another type of support, in particular on a structure already provided with at least one level N₁ of transistors, produced from a semi-conducting layer.

An example of a method for producing an integrated three-dimensional or “3D” circuit, provided with several levels of transistors superposed will now be given in connection with FIGS. 6A-6D.

A structure such as defined in connection with FIG. 1A that is then extended can be set out (FIG. 6A), as represented in FIG. 6A, on a support already provided with at least one level N₁ of transistors T₁₁, T₁₆ of which the channel region extends into a semi-conducting layer 201 resting on a substrate 200.

Then, an extension and a transfer, for example by binding, of the structure comprising the stack of N and P doped layers 14, 16 is then carried out, and of the support comprising a first level N₁ of components.

In the example illustrated in FIG. 6B, the connection elements 205 belonging to the first level N₁ are also formed above the transistors T₁₁, T₁₆ and are arranged in an insulating layer 203 arranged on the semi-conducting layer 201.

The transfer by binding is preferably implemented at a low temperature, for example of between around 100° C. and 650° C., and advantageously less than around 450° C., in order to not deteriorate the connection elements and transistors of a lower level N₁.

In the specific example in FIG. 6B, the semi-conducting layer 16 situated at the top of the stack is directly transferred on an insulting layer 203, typically made of silicon oxide. In a variant, it is possible to cover the stack of semi-conducting layers 14, 16 by an oxide layer in order to carry out an oxide-oxide type binding.

Then, the layers 10, 11 on which the stack of respectively N and P doped semi-conducting layers 14, 16 are removed, have been produced beforehand.

In the example illustrated in FIG. 6C, in particular, a BOX insulating layer 11 and a semi-conducting support layer 10 are removed. This can be achieved, for example, by steps of etching and planarisation.

Then, the separate blocks 20a, 20b are defined in the stack of doped semi-conducting layers 14, 16 (FIG. 6D).

Then, a sequence of steps such as defined above can be carried out, for example in line with FIGS. 1A-1F or in line with FIGS. 2A-2B and 1D-1F, or for example, in line with FIGS. 1A-1C and 3E-3F, or in line with FIGS. 4A-4N.

There again, the order of the layers 14, 16 of the stack produced can be reversed.

The stack of doped semi-conducting layers 14, 16 can also be provided, on a support different from that of the example of an embodiment defined above.

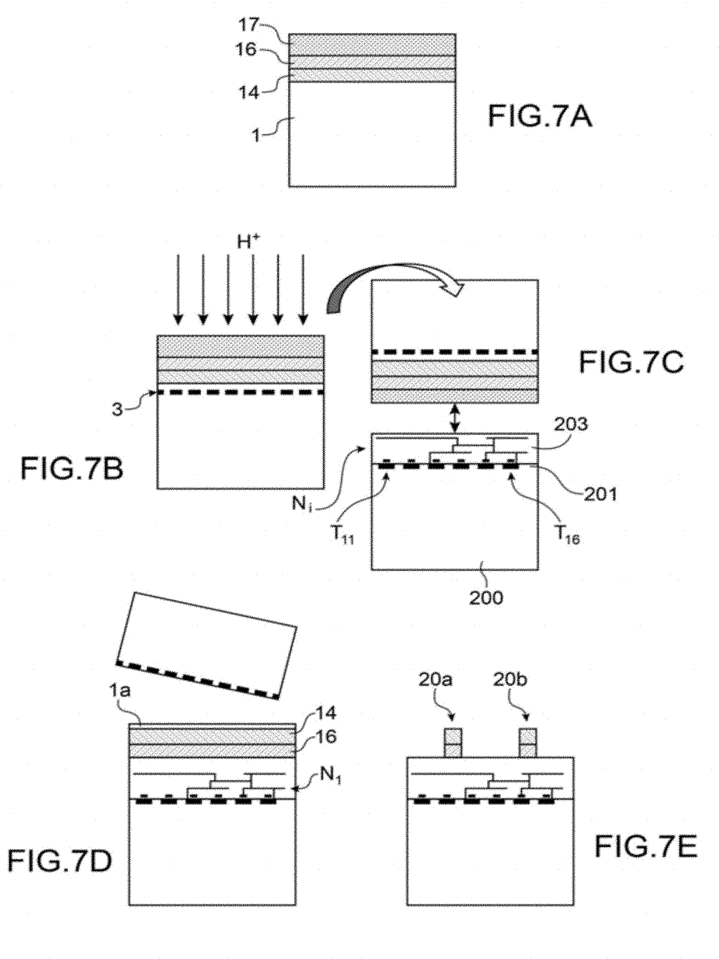

In the example of an embodiment illustrated in FIG. 7A, the stack is formed on a semi-conductor handle substrate 1, for example made of silicon, and can be covered by a dielectric material layer 17, for example made of silicon oxide.

To facilitate the removal of the handle substrate 1, an implantation can then be achieved (FIG. 7B), for example using H+ ions, of a zone of the substrate so as to form a fragilisation zone 3.

Then, the extension by molecular binding of the structure comprising the stack of N and P doped layers 14, 16 is made, and of the support comprising a first level N₁ of components. The molecular binding is here achieved between the insulating layer 203 of the support, typically made of SiO₂ and the dielectric material layer 17 typically made of SiO₂ and covering the stack of doped layers 14, 16.

FIG. 7D illustrates a later step of cutting the handle substrate at the level of the fragilisation zone 3. A later step of removing a remaining thickness 1a of the handle substrate 1 on the stack of doped semi-conducting layers 14, 16 can then be implemented. This removal is typically done by planarisation (CMP).

Once the stack is extended over the support already provided with a level N₁ of transistors, the blocks 20a, 20b can be defined in the stack of doped layers 14, 16 (FIG. 7E). Then, from these blocks 20a, 20b, junctionless transistors are formed, for example according to either of the ways defined above in connection with FIGS. 1A-1F or with FIGS. 2A-2B and 1D-1F, or with FIGS. 1A-1C and 3E-3F, or with FIGS. 4A-4H.

As suggested above, in a variant of either of the examples of the method which has just been defined, a reverse order of the N, P doped semi-conducting layers 14, 16 can be provided in the stack. For example, a first P doped semi-conducting layer made of silicon germanium can be provided, covered by a second N doped semi-conducting layer 16 made of silicon to produce the stack wherein the blocks 20a, 20b are formed. Other semi-conducting materials can also be used, such as Ge, SiC, or the semi-conductors III-V.

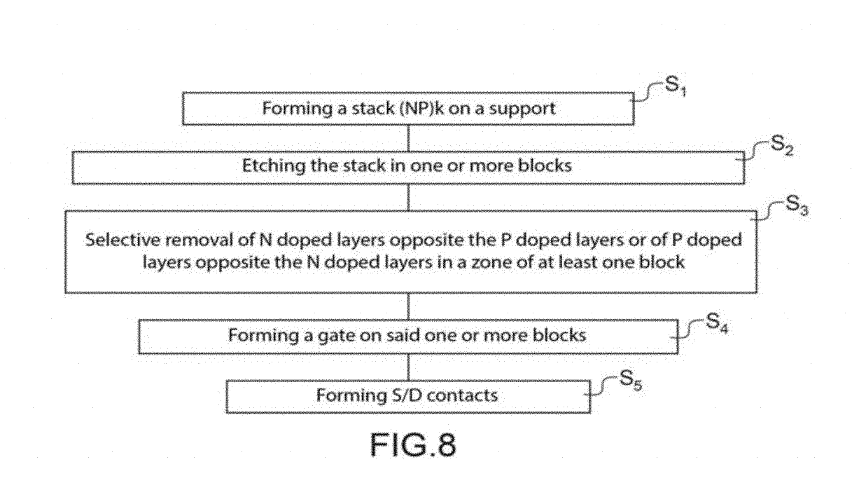

The flowchart in FIG. 8 summarises an example of a sequence of steps of a method for producing junctionless transistors on support.

Firstly, the stack of semi-conducting layers, alternatively N and P or P and N doped on the support (step S1).

Then (step S2) this stack is etched, so as to define one or more blocks, for example in the form of bars again called fins, or stacked mesas.

Then, a selective removal of the N doped layers is done opposite the P doped layers, or the P doped layers opposite the N doped layers in a zone of at least a given block, in particular a zone intended to house a transistor gate (step S3).

Then, one or more gate electrodes are formed on said one or more blocks (step S4).

Then, the source and drain contacts are produced on either side of said one or more gate electrodes (step S5).

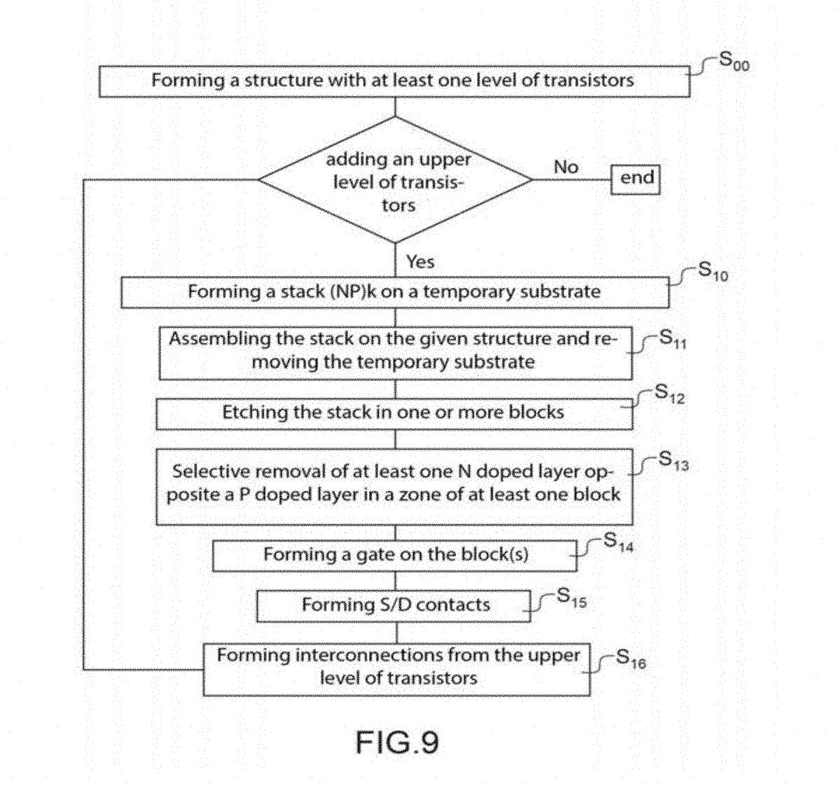

The flowchart in FIG. 9 itself summarises another sequence of steps implemented during a method for producing an N and P junctionless transistor 3D circuit, produced in an upper level.

Firstly, a structure is formed with at least one level of transistors (step S00).

Then, the stack of alternatively N and P or P and N doped semi-conducting layers are produced on a temporary handle substrate (step S10).

Then, this stack is assembled on the structure (step S11).

Then, one or more blocks are defined in this stack (step S12).

Then, a selective removal of at least one N doped semi-conducting material is done opposite a P doped semi-conducting material, or of at least one P doped semi-conducting material opposite an N doped semi-conducting material in a zone of at least one of the blocks (step S13).

Then, a gate is formed on the block(s) (step S14).

Then, contacts are produced on either side of the gate (step S15).

Then, interconnections are formed for the upper level of transistors (step S16).

Then, steps S10 to S16 may be repeated a given number of times according to the number of stages of transistors as is sought to attribute to the integrated 3D circuit.

1. A method for producing an integrated circuit provided with several superposed levels of transistors, the method comprising:
providing a structure provided with one or more transistors of a lower level covered by an insulating layer itself covered by a stack comprising at least a first doped semi-conducting layer according to a doping of a first type, N or P, and at least a second doped semi-conducting layer according to a doping of a second type, P or N, opposite said first type, the first doped semi-conducting layer and the second doped semi-conducting layer being superposed and in contact with one another,
etching the stack so as to form on the insulating layer, at least one first block and at least one second block separate from the first block, then,
removing in at least one given zone of the second block, the second given doped semi-conducting layer, while preserving in this given zone, the first doped semi-conducting layer,
forming a first gate of a first transistor arranged on the second doped semi-conducting layer of the first block and a second gate of a second transistor arranged on the first doped semi-conducting layer of the second block,
the method further comprising, prior to the formation of the first gate, the formation of insulating plugs on either side of the first doped semi-conducting layer, the insulating plugs being configured so as to electrically insulate the first gate of the first doped layer.

2. The method according to claim 1, further comprising the formation of source and drain contacts of the first transistor on the second doped semi-conducting layer on either side of the first gate and source and drain contacts of the second transistor on the first doped semi-conducting layer on either side of the second gate.

3. The method according to claim 1, wherein the second doped semi-conducting layer is fully removed in said second block.

4. The method according to claim 1, wherein after etching the stack so as to form the first block and the second block, a sacrificial gate and insulating spacers are formed on the first block, on either side of the sacrificial gate,
the method further comprising:
removal of the sacrificial gate so as to disclose the first block,
removal of the first doped semi-conducting layer in the first block by etching between the insulating spacers,
formation of a replacement gate on the first block.

5. The method according to claim 4, further comprising, the formation of embedding source and drain contacts on the first block and/or on the second block, said embedding contacts each arranged in contact with the first doped semi-conducting layer and with the second doped semi-conducting layer.

6. The method according to claim 1, wherein the stack is formed by extending over the insulating layer.

7. The method according to claim 1, wherein the stack is formed of one or more doped semi-conducting layers made of a first semi-conducting material and one or more doped semi-conducting layers made of a second semi-conducting material, the removal in the given zone of the second block being done by selective etching of the first semi-conducting material opposite the second semi-conducting material.

8. The method according to claim 7, the method further comprising a removal in a region of the first block of doped semi-conducting layers with a base of the second semi-conducting material opposite the first semi-conducting material.

9. The method according to claim 1, wherein:
the first doped semi-conducting layer is made of N doped silicon and the second semi-conducting layer is made of P doped silicon germanium, or
the first doped semi-conducting layer is made of P doped silicon germanium and the second doped semi-conducting layer is made of N doped silicon.

10. A microelectronic device with transistors distributed over several superposed levels comprising:
a structure provided with one or more transistors of a lower level covered by an insulating layer,
a second level of P and N type junctionless transistors arranged on the insulating layer, the second level comprising:
a first junctionless transistor formed in a first semi-conducting block comprising a stack of at least one first doped semi-conducting layer (14) according to a doping of a first type, N or P and at least one second doped semi-conducting layer (16) according to a doping of a second type, P or N, opposite said first doping type, the first transistor having a gate electrode for controlling a channel region extending into the second doped semi-conducting layer, the insulating plugs being provided on either side of the first doped semi-conducting layer, the insulating plugs being configured so as to electrically insulate the gate electrode of the first transistor of the first doped layer,
a second junctionless transistor formed in a second semi-conducting block separate from the first block and comprising said first doped semi-conducting layer, the second transistor having a gate for controlling a channel region extending into said first doped semi-conducting layer.

11. The device according to claim 10, the first transistor further comprising the source and drain contacts on the second doped semi-conducting layer, the second transistor comprising the source and drain contacts on the first doped semi-conducting layer.

12. The device according to claim 10, the first transistor having a channel region, in the form of a mesa or in the form of a fin, constituted from said second semi-conducting layer, the second transistor having a channel region in the form of a mesa or in the form of at least one fin, constituted from said first semi-conducting layer.

13. The device according to claim 12, the first transistor and/or the second transistor having the source and drain contacts, each embedding and arranged in contact with the first doped semi-conducting layer and with the second doped semi-conducting layer.
